(19) United States
(12) Patent Application Publication
(10) Pub. No.: US 2015/0144578 A1
(43) Pub. Date: May 28, 2015

(54) STORAGE SHELF FOR INTERNET EQUIPMENT

(71) Applicant: Robert Maiden, Flourtown, PA (US)

(72) Inventor: Robert Maiden, Flourtown, PA (US)

(21) Appl. No.: 14/550,917

(22) Filed: Nov. 22, 2014

Related U.S. Application Data
(60) Provisional application No. 61/909,189, filed on Nov. 26, 2013.

(51) Int. Cl. A47B 47/00; H05K 7/18

(52) U.S. Cl. CPC A47B 47/0075; H05K 7/186
USPC 211/26

(57) ABSTRACT

The storage shelf of the present invention is comprised generally of a flat horizontal bottom panel having opposed ends and opposed lateral sides; a flat horizontal middle panel parallel to and spaced above the bottom panel having opposed ends and opposed lateral sides; a top horizontal panel parallel to and spaced above the middle panel having opposed ends and opposed lateral sides; a first pair of upstanding opposed side walls about the perimeter of said bottom, middle and top horizontal panels; a second pair of upstanding opposed side walls about the perimeter of said bottom, middle and top horizontal panels; and a plurality of male and female connectors for individually engaging opposite ends of each respective one of said side wall members with the adjacent respective opposed ends and opposed lateral sides of each of the horizontal panels whereby each of the side walls is securable in an upright position.

### RELATED APPLICATIONS

This application claims priority to U.S. Provisional Application No. 61/909,189 filed Nov. 26, 2013. The entire contents of the above application are hereby incorporated by reference as though fully set forth herein.

### FIELD

The present invention relates to the field of shelves for storage. More specifically, the present invention relates to shelves for the storage of Internet equipment.

### BACKGROUND

Residential consumer use of the Internet first became popular through dial-up Internet access in the 1980s and 1990s. By the first decade of the 21st century, many consumers used faster, broadband Internet access technologies. The early broadband Internet service required the modem and router to be located near a host computer (usually a desktop computer) since the device(s) need to be physically connected to the computer. This meant the vast majority of homes had cables/wiring run to the room in the home where the primary computer was located which was typically a bedroom or room used as an office. The modem and router either was either laid on a desk or, in many cases, on the floor out of view since it did not need to be accessed unless there was a problem.

With the invention of wireless Internet technologies in the mid-2000s, it removed the necessity for either the modem or router to be connected to a computer. In addition, smaller computers such as laptops, notebooks, tablets, etc. become the standard home computer, replacing the larger desktop computers. Now, computer use does not need to be confined to a specific bedroom or office since all the newer smaller devices provide for unlimited portability.

Most homes still have modems and/or routers located in the same location (bedroom or office) where they were originally installed. Many of those locations no longer contain a desktop computer and many don't even have a desk anymore. As homeowners look to utilize those spaces for alternative uses, they will look for alternative locations to locate the modem and/or router. Internet service has become such a common utility service not unlike electric, water, telephone and in fact many newly constructed homes are locating the Internet devices in utility closets and basements right alongside these other services.

Utility closets and other out of sight locations do not have desks or flat surfaces to locate a router and/or modem. A small percentage of modems and/or routers do have holes or slots for the purposes of wall mounting but they are rarely utilized for a variety of reasons (i.e. wall mounting would cover up the serial numbers which are frequently needed when placing a service call). Standard shelving materials are problematic due to a variety of reasons: a) size may not be appropriate, b) no integration of power cord for electric service, c) risk of equipment falling from shelf particularly if the connected wires and/or cables are interfered with, d) flexibility to adapt both to today's standard equipment specifications (two devices—a modem and a router) and new/future specifications (one larger device “gateway”, which contains both modem and router functionality). As such, there exists a need for a storage shelf specifically designed to provide the homeowner and/or Internet service technicians a solution that allows for the safe, effective and convenient storage of Internet equipment.

### BRIEF SUMMARY OF THE INVENTION

It is the object of the present invention to address several challenges in previous attempts to store Internet equipment such as modems and routers by providing a novel design for the safe, effective and convenient storage of Internet equipment. The present invention is designed specifically for electronic equipment storage. The storage shelf is constructed from epoxy-coated wire, plastic or other similar type of suitable material, which allows electrical wires and other cables to be easily connected to the devices stored within.

The storage shelf of the present invention is comprised generally of a flat horizontal bottom panel having opposed ends and opposed lateral sides; a flat horizontal middle panel parallel to and spaced above the bottom panel having opposed ends and opposed lateral sides; a top horizontal panel parallel to and spaced above the middle panel having opposed ends and opposed lateral sides; a first pair of upstanding opposed side walls about the perimeter of said bottom, middle and top horizontal panels; a second pair of upstanding opposed side walls about the perimeter of said bottom, middle and top horizontal panels; wherein the members of said first walls pair with each horizontal panel and is fixedly associated with a different respective one of said horizontal panel opposed ends; wherein the members of said second walls pair with the horizontal panel and is fixedly associated with a different respective one of said horizontal panel opposed lateral sides; and a plurality of male and female connectors for individually engaging opposite ends of each respective one of said side wall members with the adjacent respective opposed ends and opposed lateral sides of each of the horizontal panels whereby each of the side walls is securable in an upright position.

In the preferred embodiment of the present invention, the dimensions of the adjustable storage shelf have been designed to accommodate the dimensions of the most popular modems and/or routers in use today for Internet services from manufacturers such as Motorola, Net gear, Actiontec, Apple, Linksys, Asus, Belkin, Cisco, etc. The dimensions of the popular modems and routers are generally from 7.0″ to 9.0″ in height, from 6.0″ to 10.0″ in width and from 1.5″ to 3.0″ in depth. The dimensions of the most popular “gateway” devices (single device combining router and modem functionality) are comparable in size and generally from 7.0″ to 10.0″ in height, from 6.0″ to 9.0″ in width and from 2.0″ to 3.0″ in depth. It is important to note that many of these devices are designed to allow for either horizontal or vertical orientation, which adds flexibility in terms of whether the device(s) is stored on the bottom or top shelf. Also when in single shelf mode, the single shelf has sufficient depth to store two devices side by side when both are stored in the vertical position (i.e. upright).

When evaluating the height, width and depth components of a device, the three dimensions noted above will be different based on whether the device is stored in a horizontal or vertical position (i.e. in a vertical position with cables/wires extending to the side of the adjustable storage shelf, a device with dimensions of 8.0″ in height, 7.0″ in width and 2.0″ in depth, if repositioned to a horizontal position (i.e. laid flat) with cables/wires extending to the back of the adjustable storage shelf, the dimensions change to 2.0″ in height, 8.0″ in width and 7.0″ in depth.

An additional element of flexibility is derived by purposely designing the adjustable storage shelf to have an open front and top. Should a device exceed the capacity of the adjustable storage shelf in either the depth or height dimension, the open feature provides additional space to allow the device to extend out the front or top without risk of damage to the device(s). It should be noted that as an additional measure of physical security to the device(s), for normal operations each device(s) will be connected by a wire or cable and that wire or cable can be run through the bottom of the wire shelf, back of the wire shelf or side of the wire shelf. This configuration allows the device(s) to be secured to the adjustable storage shelf without the necessity of using separate fasteners. The existence of cables and/or wires connected to the back or side of the devices adds approximately +/−2.0″ to the depth or width measurement (depending on how the device(s) are oriented on the shelf). The additional depth and/or width requirement has been considered in the design of the adjustable storage shelf capacity dimensions.

Other embodiments of the present invention can be based on changes in router and modem dimensions; however, the preferred embodiment of the adjustable storage shelf allows a maximum storage capacity.

The present invention is designed to be wall mounted using an easy four screw (or more) installation. The routers and/or modems can be stored in either a horizontal or vertical configuration.

### BRIEF DESCRIPTION OF THE DRAWINGS

FIG. 1. FIG. 1 is front perspective view of the storage shelf of the present invention.

FIG. 2. FIG. 2 is an exploded front perspective view of the storage shelf of the present invention.

FIG. 3. FIG. 3 is a front view of the front wall of the present invention.

FIG. 4. FIG. 4 is a front view of the back wall of the present invention.

FIG. 5. FIG. 5 is a front view of a first side wall of the present invention.

FIG. 6. FIG. 6 is a top view of the middle horizontal panel of the present invention.

FIG. 7. FIG. 7 is a top view of the top horizontal panel of the present invention.

FIG. 8. FIG. 8 is a front view of a second side wall of the present invention.

### DETAILED DESCRIPTION

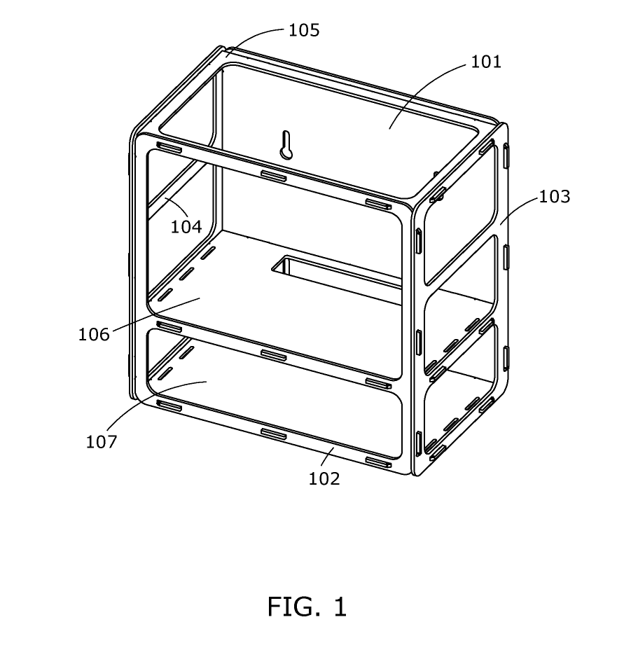

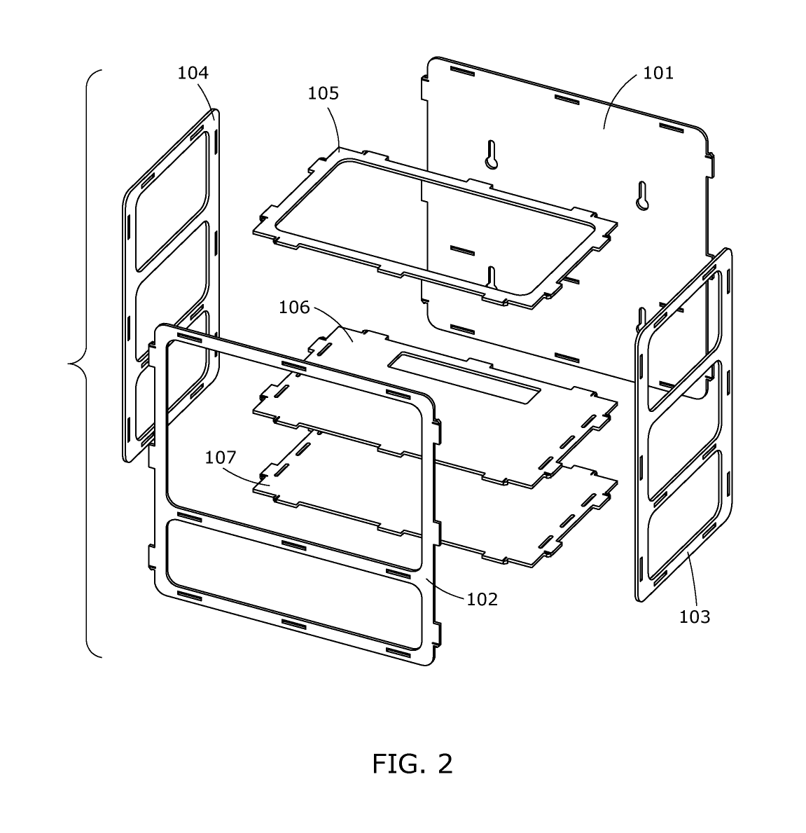

Turning to FIGS. 1 and 2, the storage shelf of the present invention is illustrated generally comprising a flat horizontal bottom panel 107 having opposed ends and opposed lateral sides; a flat horizontal middle panel 106 parallel to and spaced above the bottom panel having opposed ends and opposed lateral sides; a top horizontal panel 105 parallel to and spaced above the middle panel having opposed ends and opposed lateral sides; a first pair of upstanding opposed side walls 103 and 104, respectively, about the perimeter of said bottom, middle and top horizontal panels; and a second pair of upstanding opposed side walls 101 and 102, respectively, about the perimeter of said bottom, middle and top horizontal panels.

The first side walls 103 and 104 pair with each horizontal panel and is fixedly associated with a different respective one of said horizontal panel opposed ends. The second side walls 101 and 102 pair with the horizontal panel and is fixedly associated with a different respective one of said horizontal panel opposed lateral sides.

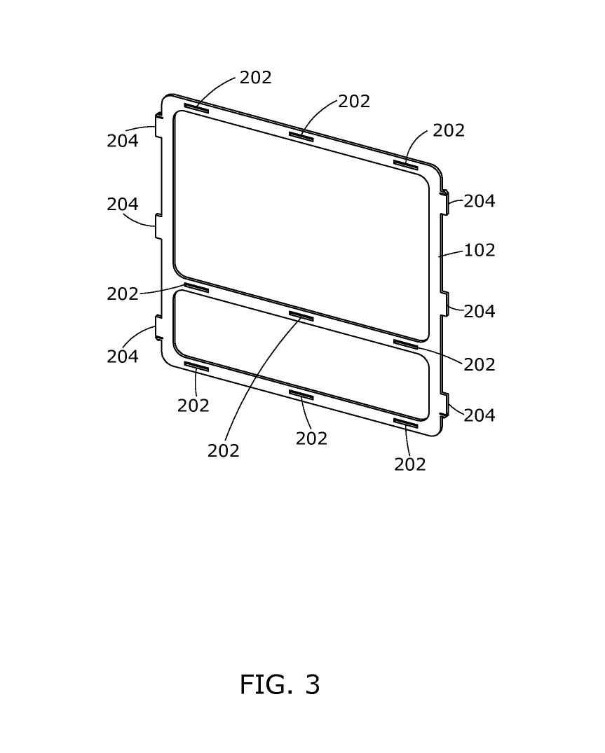

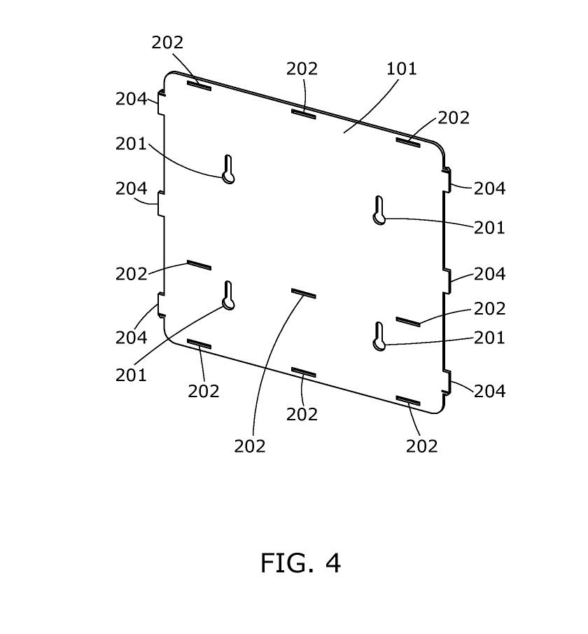

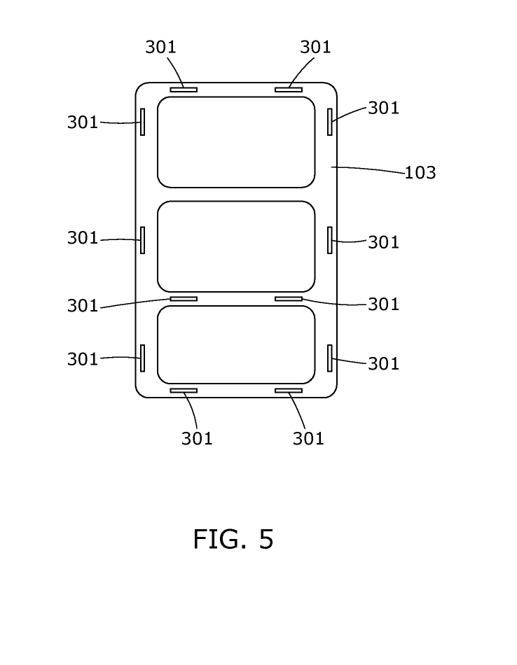

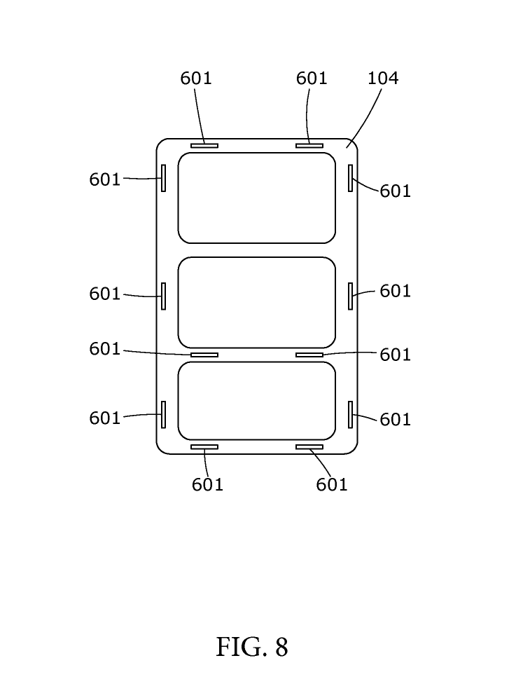

Turning to FIG. 3, side wall 102 is shown with a plurality of male connectors 204 and female connectors 202. As shown in FIG. 5, side wall 103, which is mirrored in side wall 104 shown in FIG. 8, have female connectors 301. Similarly, turning to FIG. 4, side wall 101 is shown with a plurality of male connectors 204 and female connectors 202. The male connectors 204 of side wall 102 and 101 insert into female connectors 103 of side wall 103 and 104.

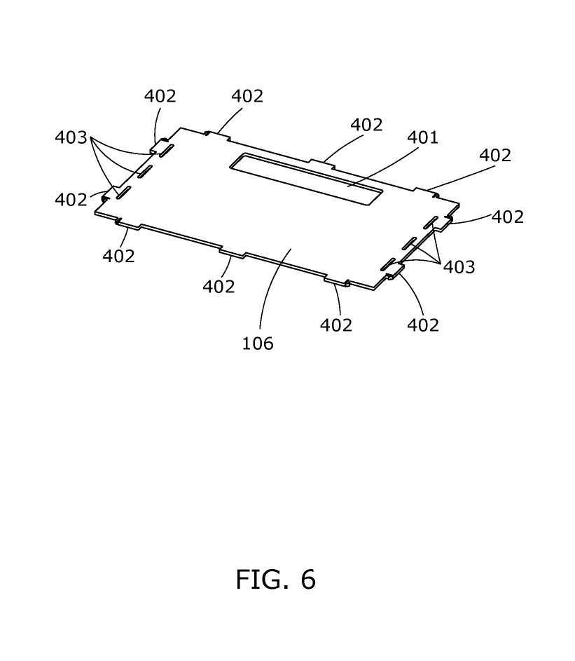

Turning to FIG. 6, middle horizontal panel 106, which mirrors bottom horizontal panel 107, is shown with male connectors 402 and female connectors 401. The male connectors 402 insert into female connectors 202 of side wall 102 and 101.

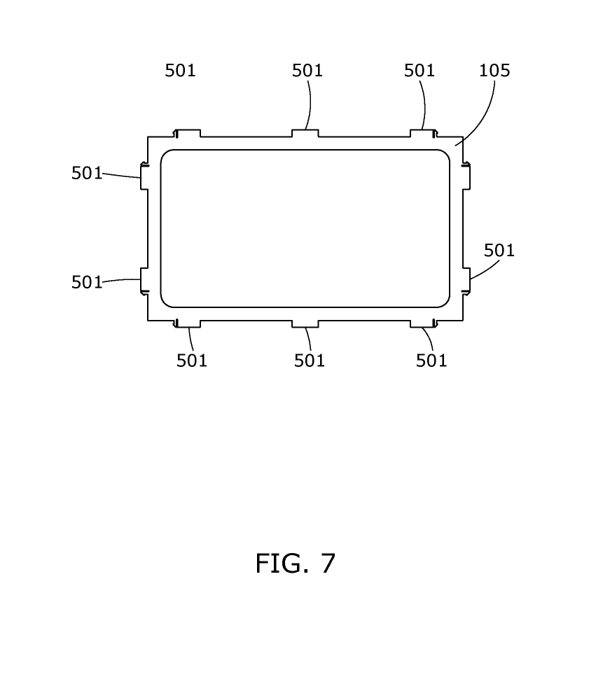

Turning to FIG. 7, top horizontal panel 105 is shown with male connectors 501. The male connectors 501 insert into female connectors 202 on opposing sides of side walls 101 and 102 and into female connectors 301 at opposing ends of side walls 103 and 104. It should be noted that the positioning of the male and female connectors might be reversed so long as they still provide compatible connections between the horizontal panels and side walls. For example, if the male connectors are located on the opposed ends and opposed lateral sides of the bottom, middle and top horizontal panels then the female connectors are located on the opposed ends and opposed lateral sides of the side walls. However, if female connectors are located on the opposed ends and opposed lateral sides of the bottom, middle and top horizontal panels then male connectors are located on the opposed ends and opposed lateral sides of the side walls.

As shown in the Figures, the horizontal panels may each have a substantially rectangular hole having an interior surface defined between a top opening at the top surface and a bottom opening at the bottom surface. In the preferred embodiment, the top horizontal panel 105 has a centered hole that extends throughout the perimeter of the panel such that moving items through the panel is made easy. The middle and bottom panels 106 and 107 each have a rectangular hole that is positioned near the back side wall 101 that takes up less than about ⅛ of the panel surface area such that the panel allows an item to sit on the shelf while still allowing the power or other cords to be threaded through the hole. In the preferred embodiment the side walls 102, 103 and 104 have a plurality of centered holes that extends throughout the perimeter of the panel such that moving items through the panel is made easy.

It is anticipated that the horizontal panels and side walls may be made of epoxy-coated wire plastic, metal, polymers or other suitable rigid material. The materials may be clear, color tinted or translucent. The storage shelf is intended to be mounted with a plurality of mounting devices against a flat surface; however, it is also anticipated that the storage shelf may also rest along the bottom surface of the bottom horizontal shelf on any suitable flat surface, such as a desktop.

In the preferred embodiment, as shown in FIG. 4, the back side wall 101 is a substantially continuous sheet with a plurality of mounting holes 201 through which the entire storage shelf may be mounted to a flat surface such as a wall or desk using a plurality of mounting devices, such as screws.

For the purposes of promoting an understanding of the principles of the invention, reference has been made to the preferred embodiments illustrated in the drawings, and specific language has been used to describe these embodiments. However, this specific language intends no limitation of the scope of the invention, and the invention should be construed to encompass all embodiments that would normally occur to one of ordinary skill in the art. The particular implementations shown and described herein are illustrative examples of the invention and are not intended to otherwise limit the scope of the invention in any way. For the sake of brevity, conventional aspects of the method (and components of the individual operating components of the method) may not be described in detail. Furthermore, the connecting lines, or connectors shown in the various figures presented are intended to represent exemplary functional relationships and/or physical or logical couplings between the various elements. It should be noted that many alternative or additional functional relationships, physical connections or logical connections might be present in a practical device. Moreover, no item or component is essential to the practice of the invention unless the element is specifically described as “essential” or “critical”. Numerous modifications and adaptations will be readily apparent to those skilled in this art without departing from the spirit and scope of the present invention.

What is claimed is:

1. A storage shelf for internet equipment comprising:
a) a flat horizontal bottom panel having opposed ends and opposed lateral sides;
b) a flat horizontal middle panel parallel to and spaced above the bottom panel having opposed ends and opposed lateral sides;
c) a top horizontal panel parallel to and spaced above the middle panel having opposed ends and opposed lateral sides;
d) a first pair of upstanding opposed side walls about the perimeter of said bottom, middle and top horizontal panels;
e) a second pair of upstanding opposed side walls about the perimeter of said bottom, middle and top horizontal panels;
1) wherein the members of said first walls pair with each horizontal panel and is fixedly associated with a different respective one of said horizontal panel opposed ends;
2) wherein the members of said second walls pair with the horizontal panel and is fixedly associated with a different respective one of said horizontal panel opposed lateral sides; and
f) a plurality of male and female connectors for individually engaging opposite ends of each respective one of said side wall members with the adjacent respective opposed ends and opposed lateral sides of each of the horizontal panels whereby each of the side walls is securable in an upright position.

2. The storage shelf of claim 1 wherein the bottom, middle and top horizontal panels further comprise a substantially rectangular through hole having an interior surface defined between a top opening at the top surface and a bottom opening at the bottom surface.

3. The storage shelf of claim 1 wherein said first side walls further comprise at least one substantially rectangular through hole having an interior surface defined between a top opening at the top surface and a bottom opening at the bottom surface.

4. The storage shelf of claim 1 wherein one said second side wall further comprises at least one substantially rectangular through hole having an interior surface defined between a top opening at the top surface and a bottom opening at the bottom surface.

5. The storage shelf of claim 1 wherein the at least one second side wall further comprises a plurality of mounting holes.

6. The storage shelf of claim 5 wherein the second side wall can be mounted through the plurality of mounting holes.

7. The storage shelf of claim 1 wherein said male connectors are located on the opposed ends and opposed lateral sides of the bottom, middle and top horizontal panels.

8. The storage shelf of claim 1 wherein said female connectors are located on the opposed ends and opposed lateral sides of the side walls.

9. The storage shelf of claim 1 wherein said female connectors are located on the opposed ends and opposed lateral sides of the bottom, middle and top horizontal panels.

10. The storage shelf of claim 1 wherein said male connectors are located on the opposed ends and opposed lateral sides of the side walls.

11. The storage shelf of claim 1 wherein the horizontal panels and side walls are clear.

12. The storage shelf of claim 1 wherein the horizontal panels and side walls are color tinted.

13. The storage shelf of claim 1 wherein the horizontal panels and side walls are translucent.

14. A storage shelf for internet equipment mounting kit comprising:
a. a storage shelf for internet equipment comprising:
i. flat horizontal bottom panel having opposed ends and opposed lateral sides;
ii. a flat horizontal middle panel parallel to and spaced above the bottom panel having opposed ends and opposed lateral sides;
iii. a top horizontal panel parallel to and spaced above the middle panel having opposed ends and opposed lateral sides;
iv. a first pair of upstanding opposed side walls about the perimeter of said bottom, middle and top horizontal panels;
v. a second pair of upstanding opposed side walls about the perimeter of said bottom, middle and top horizontal panels;
1. wherein the members of said first walls pair with each horizontal panel and is fixedly associated with a different respective one of said horizontal panel opposed ends;
2. wherein the members of said second walls pair with the horizontal panel and is fixedly associated with a different respective one of said horizontal panel opposed lateral sides;
3. wherein one second side wall comprises a plurality of mounting points;
4. wherein second second side wall further comprises at least one substantially rectangular through hole having an interior surface defined between a top opening at the top surface and a bottom opening at the bottom surface.
vi. a plurality of male and female connectors for individually engaging opposite ends of each respective one of said side wall members with the adjacent respective opposed ends and opposed lateral sides of each of the horizontal panels whereby each of the side walls is securable in an upright position.
b. a plurality of mounting devices to mount the second side wall against a flat surface along the plurality of mounting points.

15. The kit of claim 14 wherein the bottom, middle and top horizontal panels further comprise a substantially rectangular through hole having an interior surface defined between a top opening at the top surface and a bottom opening at the bottom surface.

16. The kit of claim 14 wherein said first side walls further comprise at least one substantially rectangular through hole having an interior surface defined between a top opening at the top surface and a bottom opening at the bottom surface.

17. The kit of claim 14 wherein the plurality of mounting devices are screws.

18. The kit of claim 14 wherein the horizontal panels and side walls of the storage shelf are clear.

19. The storage shelf of claim 1 wherein the horizontal panels and side walls of the storage shelf are color tinted.

20. The storage shelf of claim 1 wherein the horizontal panels and side walls of the storage shelf are translucent.
